(19) United States
(12) Patent Application Publication
(10) Pub. No.: US 2025/0357175 A1
(43) Pub. Date: Nov. 20, 2025

(54) MULTI-LAYER SYSTEM COMPRISING THIN LAYERS FOR TEMPORARY BONDING

(71) Applicant: EV GROUP E. THALLNER GMBH, St. Florian am Inn (AT)

(72) Inventor: Boris POVAZAY, St. Florian am Inn (AT)

(73) Assignee: EV GROUP E. THALLNER GMBH, St. Florian am Inn (AT)

(21) Appl. No.: 18/870,733

(22) PCT Filed: Jun. 3, 2022
(86) PCT No.: PCT/EP2022/065227

§ 371 Date: Dec. 2, 2024

(51) Int. Cl. H01L 21/683; B23K 26/20; B23K 26/50; B23K 101/40

(52) U.S. Cl. CPC H01L 21/6835; B23K 26/20; B23K 26/50; B23K 2101/40; H01L 2221/68318; H01L 2221/68381

(57) ABSTRACT

The present invention relates to a method for providing a multi-layer system, a multi-layer system and a method for bonding and debonding.

### FIELD OF THE INVENTION

The present invention relates to a method for providing a multi-layer system, a substrate stack and a method for bonding and debonding with a multi-layer system.

### BACKGROUND OF THE INVENTION

In the prior art, a plurality of methods for releasing or debonding two temporarily bonded substrates are known. The substrates are in particular a product substrate and a carrier substrate, wherein the carrier substrate enables the handling, further processing and transport of the product substrate. After the processing, the carrier substrate is separated from the product substrate.

The use of bonding adhesives is very widespread, in order to enable temporary bonding of two substrates that can be relatively easily released. This temporary adhesive coating serves in particular as an interlayer in a substrate stack. The bonding adhesives are usually polymers, in particular thermoplastics. The debonding of the two substrates takes place for example by a shearing process at raised temperature. The debonding can also take place by an additional mechanical action or chemical treatment of the bonding adhesive.

One of the newest and most important methods for the separation of substrates stacks is laser debonding. In laser debonding, laser light is coupled on the substrate side by a substrate that is as transparent as possible and is absorbed in the adjacent coating (release layer) on the rear side. The laser light is coupled preferably by a largely transparent carrier substrate. The transparency of the carrier substrate for specific electromagnetic radiation permits the most unhindered access of the photons to the release layer.

A method for separating two substrates from one another consists in using and applying a special release layer in combination with a bonding adhesive on an, in particular transparent, carrier substrate. The transparency of the carrier substrate for a specific electromagnetic radiation permits the unhindered access of the photons to the release layer. The release layer is correspondingly changed by the photons and reduces the adhesive force to the bonding adhesive. U.S. Pat. No. 10,468,286 B2 describes such a method. Depending on where the bonding adhesive has been applied—i.e. directly on the carrier substrate or after the release layer, the bonding adhesive must also be largely transparent for the selected electromagnetic radiation.

Polymers, in particular polyimide-based polymers, can be used as a release layer in laser debonding, since the latter can be removed selectively with a UV laser beam source. The separation takes place at the carrier substrate-bonding adhesive interface. The UV laser beam source used for this requires carrier substrates made of glass, which have the necessary transparency for the specific electromagnetic radiation in the UV region. U.S. Pat. No. 9,827,740 B2 shows a system consisting of a bonding adhesive and a release layer made of polyimide, which has been applied directly on the carrier substrate made of glass. In U.S. Pat. No. 10,703,945 B2, the bonding adhesive contains a light-absorbing material, as a result of which only a polymer layer is used for the simultaneous bonding and release.

The release layer can in particular also be a metal layer. In WO 2011/159456 A2, an adhesive layer with a metal layer for example is used for laser debonding. A separation of product substrate and carrier substrate is possible due to an intense absorption of the laser radiation by the metal coating. Bonding of two substrates, however, is not possible without bonding adhesive in WO_2011/159456_A2. U.S. Pat. No. 9,269,561 B2 also shows a release layer consisting of a bonding adhesive and a metal coating between a Si-carrier substrate and a product substrate.

U.S. Pat. No. 10,112,377 B2 discloses different materials, which can be used for a release layer for laser debonding, consisting of a single layer. Here too, apart from the release layer, a bonding adhesive is required for the temporary bonding of the substrates.

The use of polymeric bonding adhesives has the drawback that cleaning of the surfaces is required after the UV laser debonding, in order to remove bonding adhesive residues. Furthermore, the demands of 3D stacks and CMOS-compatible processes lead to high-quality silicon carrier substrates being required and the latter are not transparent in the UV region. In addition, the polymer-based bonding adhesives are not heat-resistant at raised temperatures.

If a metal layer is applied on the product substrate and/or on the carrier substrate and used as a bonding layer, further layers are first required in the prior art in order to enable careful laser debonding which is largely destruction-free, since the surface of the coating is stripped destructively. This at least one further layer serves as protection for the product substrate and is in particular an antireflection coating (AR coating). Further protective layers are for example relaxation layers. In WO 2015/014265 A1, such an AR coating and a relaxation layer are disclosed in addition to the metal layer, which is used as a release layer.

A problem in the prior art consists in the fact that, due to the exposure to laser beams, destruction of the substrates, in particular of expensive functional components of the substrates, can take place. Further layers are therefore required in addition to the release layer, in particular polymer-based adhesive layers. Furthermore, the bonding adhesives for laser debonding that are curable in the UV region are not compatible with carrier substrates made of silicon. Additional layers are therefore required in the prior art and serve either to protect the substrates and/or as an adhesive layer for the bonding of the substrates.

Many products from the semiconductor industry, such as for example electronic and optoelectronic components, partly consist of layer sequences of unlike materials. Many of the multi-layer systems are used in bonding processes, but at the same time are required for many production processes in which bonding and debonding take place. In laser bonding, in particular, only lasers of specific wavelengths can be operated efficiently.

It is the aim of the invention, therefore, to eliminate at least in part, in particularly to completely eliminate the drawbacks listed in the prior art. In particular, it is an aim of the invention to specify an improved method for providing and using multi-layer systems for bonding and debonding.

### SUMMARY OF THE INVENTION

The aim of the invention is achieved with the features of the coordinated claims. Advantageous developments of the invention are given in the sub-claims. All combinations of at least two features stated in the description, the claims and/or the drawings also fall within the scope of the invention. In the case of stated value ranges, values lying within the stated limits should also be deemed to be disclosed as limiting values and can be claimed in any combination.

Accordingly, the invention relates to a method for providing a multi-layer system comprising at least two layers, in particular for the temporary bonding of substrates to form a substrate stack, with the following steps in the following sequence:
i) provision of a multi-layer system,
ii) determination of a degree of absorption of the multi-layer system for laser radiation of a specific wavelength,
iii) varying at least one parameter of the multi-layer system,
iv) determination of the degree of absorption of the multi-layer system for the laser radiation of the specific wavelength with the at least one parameter varied according to step iii),
v) repetition of steps i) to iv) until the degree of absorption is greatest, wherein in each case in step i) the multi-layer system with the greatest degree of absorption is provided.

A multi-layer system includes at least two layers. The layers preferably have a uniform layer thickness and are arranged flat above one another, wherein the layer can also be applied structured instead of flat. The same material is present inside the layers of the multi-layer system. The layers are so-called thin layers or thin films, particularly preferably with a layer thickness in the nanometer range. Advantageously, known multi-layer systems can be used with regard to the structure and arrangement of the layers.

The provision in step i) also includes the provision of material data of the multi-layer system, so that a computer-assisted calculation or simulation for the respective parameter can also be used in the determination. In other words, the parameter of the multi-layer system in respect of a degree of absorption is determined in different combinations and in each case the greatest is selected. In the repetition, technically appropriate values in the renewed variation or adaptation of the multi-layer system are selected depending on the parameter. The wavelength of the laser radiation, on the basis of which the respective degree of absorption or degree of absorption comparison is carried out, remains constant.

Parameters can for example be the sequence or the structure of the layers of the multi-layer system as well as the layer thicknesses. In the determination of the degree of absorption, the latter can be measured or calculated for the respective case. A simulation of the multi-layer systems preferably takes place with regard to the respective parameter.

In the search for solutions for the drawbacks described in the prior art, it has surprisingly been found that in the case of specific parameters the respectively provided multi-layer systems can be markedly improved in the absorption behaviour, in particular in the case of established multi-layer systems. In this way, multi-layer systems or material combinations can be used in other areas of application. Furthermore, thinner layers can be used for the debonding and multi-layer systems can be used without further polymeric adhesive/adhesive layers and without antireflection layers for the bonding and at the same time debonding.

Furthermore, due to a greater degree of absorption, the energy input and thus the heat input is minimised in substrates arranged behind the multi-layer system. Advantageously, therefore, the destruction in the context of laser debonding can be prevented.

In a preferred embodiment of the method for providing a multi-layer system, provision is made such that the at least one parameter of the multi-layer system is a layer thickness of a layer of the multi-layer system. In other words, therefore, the layer thickness of a specific layer of the multi-layer system is varied, i.e. increased or reduced, in order to achieve the greatest possible degree of absorption. Surprisingly, it has been found that a greater degree of absorption can be achieved by changing the layer thickness in a multi-layer system comprising thin layers by interference effects. The degree of absorption can thus advantageously be increased significantly by means of the method by changing the thickness of a layer. By the systematic variation, otherwise unnoticed effects concerning the absorption behaviour remain undetected. An in particular interference-optimised layer structure for a multi-layer system is thus advantageously ascertained by means of the method. The wavelength of the laser radiation, for which the degree of absorption should be maximum, remains the same.

In laser debonding, one is limited to laser radiation of specific wavelengths, since only the latter can be generated efficiently. In this regard, it has thus also been surprisingly found that for specific wavelengths a greater degree of absorption can be achieved by varying the layer thickness. By systematic changing of the layer thickness of the individual layers of the coating on a multi-layer system, a greater degree of absorption can surprisingly be achieved, as a result of which a multi-layer system can not only be used as a bonding layer, but also at the same time as a release layer in the laser debonding.

The provision of the multi-layer system can advantageously take place without a change or replacement of the materials and thus enables existing systems (i.e. coatings and multi-layer systems known to the expert in the semiconductor industry) to be used. The existing multi-layer systems or materials can also be partially changed in the arrangement of the materials. In particular, however, the layer thicknesses are adapted relative to the absorption behaviour, in particular absorptivity and reflectivity of the entire multi-layer system, since it has surprisingly been found that, with the same or smaller total thickness of the multi-layer system, the same or greater degrees of absorption can be achieved. In this way, a layer thickness-optimised multi-layer system can advantageously be used not only for bonding, but also for debonding. The energy input into other materials can advantageously be kept small. In addition, material can be saved and the thickness of the multi-layer system can be reduced. By means of a targeted reduction in the retention forces of the multi-layer system of the substrate stack to be debonded by irradiation with laser radiation of a specific wavelength, the multi-layer system can also advantageously be used as a debonding layer.

In a preferred embodiment of the method for providing a multi-layer system, provision is made such that the at least one parameter of the multi-layer system is a layer thickness of a further layer of the multi-layer system. In addition to the layer thickness of the one layer, the layer thickness of a further layer of the multi-layer system is thus advantageously varied at the same time. An efficient and rapid provision of a multi-layer system with the greatest possible degree of absorption with respect to laser radiation of the specific wavelength and layer structure is thus advantageously possible by changing the thickness. If the multi-layer system comprises three layers, one layer thickness is preferably kept constant and the simulation or the test series for the two adjacent layers is ascertained.

In a preferred embodiment of the method for providing a multi-layer system, provision is made such that the wavelength in the determination in step ii) and iv) lies between 1100 nm and 10,000 nm, preferably between 1100 nm and 5000 nm, still more preferably between 1500 nm and 2500 nm. In research carried out on multi-layer systems, it has also been found that, for laser debonding with the multi-layer systems including thin, in particular polymer-free layers, the degree of absorption especially in specific wavelength ranges can be influenced by the varying of parameters. The laser debonding of the multi-layer systems according to the invention is preferably carried out in the infrared region.

Furthermore, the invention relates to a substrate stack, comprising at least one multi-layer system provided according to the method for providing a multi-layer system with at least two layers of different materials. The multi-layer system is preferably constituted as an interlayer and joins two substrates to form the substrate stack. The multi-layer system has a layer structure optimised with regard to layer thicknesses, wherein the layer thicknesses are selected such that the multi-layer system has the greatest possible degree of absorption for a specific wavelength, wherein the layers can at the same time be kept as thin as possible. The multi-layer system is thus adapted in an optimum manner in respect of the layer thickness or another parameter for a highest possible absorption of electromagnetic radiation of a specific wavelength. The multi-layer system can thus advantageously be used as a bonding layer and as a debonding layer in the substrate stack.

The substrate stack can thus be separated by means of laser radiation destruction-free, efficiently and easily or in particular a product substrate can be released. The multi-layer system has preferably been produced on a substrate and has then been bonded with a further substrate, so that the multi-layer system can be used as a bonding layer and at the same time at a debonding layer.

In a preferred embodiment of the substrate stack, provision is made such that the multi-layer system has a total thickness between 1 nm and 10 μm, still more preferably between 5 nm and 2 μm, most preferably between 10 nm and 1 μm, with utmost preference between 10 nm and 500 nm. The substrate stack is thus stable and small. In addition, debonding along or in the region of the multi-layer system can advantageously be carried out easily and efficiently.

In a preferred embodiment of the substrate stack, provision is made such that the respective layers of the multi-layer system each have a layer thickness between 1 nm and 1 μm, preferably between 1 nm and 500 nm, still more preferably between 1 nm and 250 nm. It has surprisingly been found that, even with very thin layers, a high degree of absorption can be achieved by optimisation of the layer thicknesses. The interferences can thus be produced in multi-layer systems particularly well for thin layers with layer thicknesses in the sub-wavelength range in respect of the laser radiation. In particular, a high degree of constructive interference of the laser radiation in the multi-layer system can advantageously be achieved by the combination of the layer thicknesses.

In a preferred embodiment of the substrate stack, provision is made such that the multi-layer system comprises at least one layer with a layer thickness between 10 nm and 100 nm, preferably between 20 nm and 100 nm, still more preferably between 25 nm and 75 nm, most preferably between 35 and 65 nm. In the course of the development of the method for providing a multi-layer system and the substrate stack comprising the multi-layer system, it has been found that a particularly high increase in the degree of absorption can be achieved if at least one layer has the corresponding layer thickness.

In a preferred embodiment of the substrate stack, provision is made such that at least one layer of the multi-layer system comprises, preferably consists of, titanium (Ti), aluminium (Al), aluminium nitride (AlN), tantalum nitride (TaN), germanium (Ge), titanium nitride (TiN) or copper (Cu). The layer thickness particularly preferably amounts to between 25 and 75 nm.

In a preferred embodiment of the substrate stack, provision is made such that at least one layer of the multi-layer system includes amorphous silicon dioxide (SiO2). The layer thickness of this layer of the multi-layer system is preferably greater than the other layers or the other layer. The layer thickness preferably amounts to more than 100 nm, more preferably more than 200 nm.

In a preferred embodiment of the substrate stack, provision is made such that the substrate stack at least comprises a carrier substrate and a product substrate, wherein the carrier substrate is bonded with the product substrate by the multi-layer system. The multi-layer system is thus arranged as an interlayer at the same time as a bonding layer between the carrier substrate and the product substrate. Debonding can thus be carried out particularly quickly and efficiently with the substrate stack.

In a preferred embodiment of the substrate stack, provision is made such that the multi-layer system, preferably the substrate stack, does not comprise any polymer-based bonding adhesive. In other words, an additional bonding layer or auxiliary layer can be dispensed with due to the high degree of absorption of the multi-layer system. The substrate stack is particularly preferably free from polymer-based materials, so that the substrate stack can be processed at particularly high temperatures. In addition, the adhesive layer and thus a subsequent laborious removal of residues can advantageously be dispensed with.

In a preferred embodiment of the substrate stack, provision is made such that the multi-layer system, preferably the substrate stack, does not comprise an anti-reflection layer. The antireflection layer usually arranged on the side of the multi-layer system facing away from the laser beam or the side of the interlayer on which the bonding layer is arranged in laser debonding can be dispensed with on account of the high degree of absorption of the optimally structured multi-layer system. In addition, destruction even without an antireflection layer can advantageously be prevented by the multi-system.

In a preferred embodiment of the substrate stack, provision is made such that the at least one substrate arranged on the multi-layer system, in particular a carrier substrate, includes silicon. In this way, the multi-layer system can advantageously be irradiated through the substrate with laser radiation with a wavelength greater than 1300 nm. The laser debonding can thus advantageously be carried out from the rear side of the substrate stack.

In a preferred embodiment of the substrate stack, provision is made such that the degree of absorption of the multi-layer system with respect to the laser radiation of a specific wavelength is greater than 0.5, preferably greater than 0.65, more preferably greater than 0.75, still more preferably greater than 0.85, most preferably greater than 0.9. In this way, it can be ensured that destruction of the other substrate arranged behind the multi-layer system, in particular the product substrate, is prevented during debonding of the substrate stack.

In a preferred embodiment of the substrate stack, provision is made such that the multi-layer system comprises precisely 3 layers, wherein two of the three layers includes the same material and are separated from one another by a remaining layer. The layers of the multi-layer system adjacent to the substrates are thus made from the same material and preferably include a smaller layer, which is preferably a layer made of metal.

In a preferred embodiment of the substrate stack, provision is made such that the substrate stack is debonded by irradiation of the multi-layer system with laser radiation of a specific wavelength.

Furthermore, the invention relates to a method for the bonding of substrates to form a substrate stack according to the invention with the following steps,
1) Provision of a first substrate, in particular a carrier substrate,
2) Bonding of a second substrate, in particular a product substrate, to the first substrate.

The substrate provided in step 1) acts in particular as a bonding layer. Bonding can be carried out particularly easily and efficiently with the multi-layer system.

The layers of the multi-layer system can be arranged on the first substrate and/or on the second substrate.

Furthermore, the invention relates to a method for the debonding a substrate stack with the following steps,
a) Provision of a substrate stack according to at least one of claims 5 to 13,
b) irradiation of the multi-layer system through at least one substrate of the substrate stack with laser radiation of a specific wavelength and then
c) separation of the substrate stack in the region of the multi-layer system.

The debonding or laser debonding can be carried out particularly easily, reliably and quickly with a substrate stack or a substrate stack comprising a thickness-optimised multi-layer system.

Since the arrangement of the layers is often predetermined for process-related reasons or for reasons relating to the intended use and by the respective substrates used, the layer thickness optimisation in respect of the degree of absorption is an unexpected and extremely useful effect. Particularly since it provides a previously undetected possibility for adapting the absorption behaviour of thin layers for laser bonding. The sequence of the materials in the multi-layer system is usually retained for purpose-related reasons.

In an exemplary embodiment of the method for providing a multi-layer system, an optimisation of the layer thicknesses is first carried out for each individual layer L1 to Ln of a given multi-layer system comprising layers L1 to Ln, preferably with three layers (L1 to L3), particularly preferably with two layers (L1, L2), wherein the absorption of the entire multi-layer system is determined numerically and also measured experimentally.

Parameters such as carrier substrate (preferably Si), wavelength (preferably in the IR region suitable for the Si carrier substrate) and the laser entry angle (for example in the main beam as 0°, i.e. perpendicular to the surface) are constant. The layer thicknesses can be simultaneously varied in the simulation with a constant laser wavelength. A thickness distribution with the maximum absorptivity of the multi-layer system is thus ascertained in the simulation. In the test, the substrate stack with the multi-layer system is tested at defined layer thicknesses with regard to remaining bonding strength, ablation form, homogeneity and stability of the production and processing parameters.

In a preferred embodiment of the method, provision is further made such that the material layers of the multi-layer system are first confirmed in the arrangement of the materials and then optimised in their layer thickness, in such a way that a maximum light absorption is achieved and reflection losses are minimised. The substrate stack produced by bonding and optimised for laser debonding with the multi-layer system (in particular as an interlayer) can thus be separated again in a subsequent process step by laser debonding.

The separation of the substrates takes place by debonding or delamination along the interface by means of laser irradiation. In a preferred embodiment, laser irradiation through the carrier substrate with light of a selected wavelength, intensity and pulse duration (ΔT in the range us to fs) takes place in the debonding. The pulses particularly preferably lie in the picosecond region.

The release of the product substrate from the carrier substrate takes place in the method for the debonding of a substrate stack by focusing of laser radiation of a specific wavelength through the carrier substrate onto the multi-layer system optimised via interference and thicknesses. At least one layer of the multi-layer system is destroyed, or its adhesive properties are markedly reduced, by fusion, vaporisation and/or sublimation with photo- or thermochemical conversion of the multi-layer temporary bonding layer.

An important aspect of the method for providing a multi-layer system is the determination and provision of a multi-layer system with the greatest possible degree of absorption, preferably with the same or a smaller total thickness. The degree of absorption of a multi-layer system, which has a layer structure with an interference-optimised layer thickness distribution, is thus as great as possible or close to 1 (100%). A higher degree of absorption can be achieved by adapting the layer thicknesses of the individual layers in a multi-layer system, which makes it possible to use an existing multi-layer system as a bonding layer and at the same time as a release layer in the laser debonding.

The arrangement of the individual layers is usually given by the bonding process and the standard bonded substrate stack known to the expert in the semiconductor industry. The optimisation of the multi-layer system thus preferably takes place without a change of material and enables existing systems to be used. The existing materials are optimised in the layer thickness with regard to absorptivity and reflectivity of the entire multi-layer system. If for example an optimum layer thickness is exceeded or fallen below, the interferences change and the absorption of the multi-layer system is thus reduced. The layer thickness of the individual layers lies in the nm region and thus enables a high interaction with the electromagnetic waves. Furthermore, a layer structure optimised via interference enables simplified laser debonding, since the product substrate does not have to be protected with an additional antireflection coating (AR). Since the multi-layer system is used for bonding and laser debonding, no additional bonding adhesive is preferably required for the bonding.

The layer thicknesses of the individual bonding and laser debonding layers are in particular dependent on the method (CVD, PVD, MBE, oxidation at the surface, etc.). They lie in particular between 10 nm and 500 nm, preferably between 20 nm and 100 nm.

The optimisation of the multi-layer systems is in particular a graphic optimisation with preferably two parameters which are optimised. A multi-dimensional (i.e. more than two parameters) optimisation is possible, but is less preferable. The layer thicknesses are determined in the optimisation in particular by simulations. In the test, further criteria for the laser debonding are checked with the layer thicknesses selected from the simulation, in particular process efficiency and stability as well as residual bonding strength, ablation form and homogeneity.

If the layers, the substrate and the carrier substrate from a given substrate stack are known, layer thickness d of the individual layers of the multi-layer system is the easiest to control and change. Layer thickness d of the individual layers of the multi-layer system is thus primarily changed or varied. The laser wavelength and the laser angle, i.e. angle of incidence in particular remain unchanged. If a multi-layer system consists of two layers, both layer thicknesses d1 and d2 can be varied simultaneously. The multi-layer systems includes a plurality of layers L1 to Ln, preferably L1 to L3. The selected parameters, in particular for example two layer thicknesses d1 and d2 are varied and the degree of absorption in the debonding structure is calculated and represented graphically. The degree of absorption in the debonding structure should be as high as possible. Up to a maximum of three layers are preferably used to maximise the absorption. The area with high absorption in the represented graphic must be large enough in order not to be too sensitive to changes. Layer thicknesses d1 and d2 from the area with high absorption are selected for the thickness of layers L1 and L2.

The method for the provision of a multi-layer system, the multi-layer system and the method for bonding and debonding are particularly advantageous, since:
Laser debonding becomes possible for the first time for some bonding layers by an optimised multi-layer system,
The combination of a plurality of very thin layers enables a high degree of absorption to be achieved via interferences of the layers of the multi-layer system,
The layer thicknesses are reduced (nm region) by the optimisation of the individual layer thicknesses of a multi-layer system, as a result of which less material has to be applied,
The available pulse energy is less by orders of magnitude with shorter pulses (in the region of J for high-power-lasers compared to μJ for the “ultra-rapid” pico-second and femto-second lasers), so that the total energy input into the material to be processed is reduced, which leads to a smaller heat-damaged zone on account of the shorter action time and the resultant reduced thermal diffusion,
Higher efficiency of the separation by debonding or delamination along the interface by means of laser irradiation with ultrashort laser pulses,
no further layers required for the protection of the product substrate (antireflection (AR) layer) and
bonding adhesive is not necessary.

The production of the substrate stack with a multi-layer system is thus not only suitable for bonding, but also for laser debonding of a substrate stack. In particular, existing materials of a multi-layer bonding layer (multi-layer system) are used between the carrier substrate and the product substrate. Subsequently, the selection of the transparent carrier substrate for the substrate-side irradiation with laser radiation takes place. Silicon as a carrier substrate, for example, is transparent at a wavelength λ>1300 nm or at λ>1900 nm, so that lasers in the near infrared (NIR) and mid-infrared (MIR) are selected here. Silicon is therefore preferred in the present case as a carrier substrate and laser debonding in the infrared region as possible. The carrier substrate (Si) and the laser source with a laser wavelength (selection with the use with Si carrier substrates: for example 1940 μm, 1960 μm, or 2030 μm) are thus established.

The optimum layer thickness or layer thicknesses of the individual layers of the multi-layer system, which should not be exceeded or fallen below, are thus determined. The material layers are optimised in their layer thickness in particular in a simulation, in such a way that a maximum light absorption (absorptivity) is achieved and reflection losses are minimised. A plurality of layer thicknesses, preferably two, are simultaneously varied. A substrate stack with a multi-layer system optimised with the layer thicknesses can then be laser debonded by laser irradiation with a selected wavelength, intensity and pulse duration (ΔT in the range of us to μs). The complete release or separation of the product substrate by debonding or delamination along the interface by means of the laser irradiation takes place in the region of the multi-layer system.

An exemplary method for providing a multi-layer system, in particular for the temporary bonding of substrates, comprising:
a first layer of a first material with a first layer thickness and
a second layer of a second material with a second layer thickness,
wherein the method comprises at least the following steps in the following sequence:
a) determination of the degree of absorption of the multi-layer system for laser radiation of a specific wavelength for different first layer thicknesses, wherein the second layer thickness is constant,
b) selection of the first layer thickness, so that the degree of absorption of the multi-layer system is at a maximum,
c) determination of the degree of absorption of the multi-layer system for laser radiation of the specific wavelength for different second layer thicknesses, wherein the first layer thickness is constantly the first layer thickness selected in step b),
d) selection of the second layer thickness, so that the degree of absorption of the multi-layer system is at a maximum,
e) provision of the multi-layer system with a first layer thickness according to step b) and a second layer thickness according to step d).

To this extent, this exemplary method describes the manner in which the respective optimum layer thicknesses for achieving a greatest possible degree of absorption of the multi-layer system can be determined. It has surprisingly been found that the thin layers of the multi-layer system have high degrees of absorption despite the small thicknesses of the layers, since the layer thicknesses are arranged or configured in the optimum manner for laser debonding. In particular, the occurrence of interferences in the multi-layer systems with thin layers with specific layer thickness distributions is responsible for the higher degree of absorption. If, for example, an optimum layer thickness is exceeded or fallen below, the interferences change and the absorption of the multi-layer system is reduced. The layer thickness of the individual layers lies in the nm region and thus enables a high interaction with the electromagnetic waves. Furthermore, a layer structure optimised via interference enables simplified laser debonding, since the product substrate does not have to be protected by an antireflection coating (AR). Since the multi-layer system is used for bonding and laser debonding, an additional bonding adhesive is preferably not required for the bonding.

The (temporary) bonding layer includes a multi-layer system. The multi-layer system serves simultaneously as a bonding layer and as a release layer during the laser debonding. The temporary bonding layer is preferably a plurality of layers, which are used for the bonding and debonding process. The materials of the multi-layer system are known to the person skilled in the art. The temporary bonding layer includes a plurality of layers, which are optimised in their thickness in such a way that the multi-layer system leads to maximum absorption of the laser radiation. The layer structure optimised via interference enables improved and simpler laser debonding, wherein no additional layers for the protection of the substrates or for the bonding of the substrates, such as for example an antireflection (AR) protection layer and/or a relaxation layer and/or a bonding adhesive, are required. The individual layers can for example serve as selective absorber layers or as phase-shifters.

The product substrate is separated from the carrier substrate by means of the optimised multi-layer system during laser debonding, wherein the damage to the product substrate and/or to the carrier substrate is largely minimised or is eliminated as far as possible. A prerequisite is in particular the intense absorption of the laser light by the multi-layer system optimised via interference. The thermal conduction during the removal is minimised or largely negligible due to the use of ultrashort laser pulses. The distribution of the absorbed laser energy is determined by the absorption in the multi-layer material system, which is triggered by linear and non-linear processes during the irradiation of the material system by ultrashort laser pulses, preferably in the ps region. On account of the high photon densities, which can be generated with the use of very short pulses, a rapid removal of the material takes place, so that no or only very little thermal input into the remaining adjacent substrate takes place.

The separation by debonding or delamination along the interface by means of laser irradiation requires a maximum radiation absorption of a release layer, which includes a multi-layer system, by linear and/or non-linear processes. The debonding primarily takes place thermally, in particular by the emergence of gases, but also in part chemically. The middle layer is for the most part the absorptive layer and absorbs the energy of the laser radiation. The auxiliary layer(s) react/interact with the absorptive layer.

The transparency of the carrier substrate for a specific electromagnetic radiation permits the largely unhindered access of the photons to the multi-layer system. The carrier materials are for example (Si), glass, Sapphire and silicon carbide. The use of carrier substrates made of glass does enable the use of UV lasers, but has a number of drawbacks such as poor thermal conductivity and incompatibility with specific semiconductor processes and semiconductor processing installations. Carrier substrates made of silicon (Si) are therefore preferred. Since Si substrates are not transparent for the UV spectrum, lasers in the infrared (IR) region, preferably in the mid- and near infrared (MIR and NIR) are used, since the carrier wafers of silicon are transparent for the selected wavelengths in the mid- and near IR. Lasers with high efficiency and high economy have for a long time only been available with specific wavelengths. Moreover, the accessible wavelength range is markedly restricted on account of other material properties. The laser source and the laser wavelength are thus constant.

An exemplary method for the temporary bonding of a product substrate with a carrier substrate including silicon (Si) with at least the following steps:
production of a multi-layer system as a bonding and release layer for temporary bonding to a carrier substrate and/or a product substrate,
bonding of the product substrate with the carrier substrate.

No bonding adhesives are required for the temporary bonding. The bonding is produced in particular by direct bonding methods or further known bonding techniques such as for example metal diffusion bonding or anodic bonding.

Furthermore, a substrate stack, in particular produced with a method comprising a product substrate and a carrier substrate, wherein the product substrate and the carrier substrate are bonded by means of a multi-layer system as a temporary bonding layer, can be separated in a simplified manner by laser debonding by means of laser irradiation of the multi-layer system.

The substrate stack preferably comprises the following components:
A product substrate,
a multi-layer system with a layer structure optimised via interference for the temporary bonding and laser debonding in the IR region,
a carrier wafer made of silicon, transparent for selected wavelengths in the mid- and near IR.

In a preferred embodiment, the layers of the multi-layer system are produced over the whole area. In a less preferred embodiment, at least one of the layers is applied structured.

An exemplary method for the laser debonding of a product substrate from a carrier substrate including silicon, wherein the product substrate and the carrier substrate are bonded by a multi-layer system and form a substrate stack, comprises in particular at least the following steps:
Mounting and fixing of the substrate stack on a substrate holder,
focusing of debonding radiation, in particular of a laser beam of a laser source, through the carrier substrate onto the multi-layer system optimised via interference and thus fusion, vaporisation and/or sublimation of the multi-layer temporary bonding layer,
release of the product substrate from the carrier substrate.

An antireflection layer as a protection layer is not required on the product substrate. By means of a targeted energy input and energy conversion in the multi-layer system of the bonding layer, the in particular thermal and/or photothermal loading of the substrates, in particular the functional components of the substrates, is minimised.

Furthermore, an exemplary method for the production and processing of a substrate stack comprises the following steps:
provision of a carrier substrate, which is largely transparent for light of a predetermined wavelength, in particular a silicon carrier wafer,
production of an optimised multi-layer system as a bonding and release layer for the temporary bonding on the carrier substrate and/or on the product substrate,
bonding of the product substrate with the carrier substrate,
processing of the product substrate,
release of the product substrate from the carrier substrate by focusing of debonding radiation, in particular a laser beam of a laser source, through the carrier substrate onto the multi-layer system optimised via interference and thus fusion, vaporisation and/or sublimation of the multi-layer temporary bonding layer.

According to a preferred embodiment, the laser source is a pulsed laser source, in particular in ultrashort pulsed laser source.

In agreement with a further preferred embodiment, the ultrashort pulsed laser source is a femtosecond laser source.

According to a further preferred embodiment, the system is additionally provided with a scanner for scanning the pulsed laser beam.

Depending on the action of the laser radiation during the absorption by the multi-layer system, the multi-layer system is separated by delamination/lift-off and/or ablation from the substrate. The debonding preferably takes place along the interface between the carrier substrate and the multi-layer system (delamination).

In a preferred embodiment, the release means is the substrate holder, on which the product substrate and the carrier substrate are each fixed or can be fixed. The separation takes place for example by a parallel displacement of the substrate and the carrier substrate with respect to one another or by raising the substrate or the carrier substrate. Both are known to the person skilled in the art and will not be described further. Further mechanical, physical and/or chemical aids can be used for the separation.

The laser acts on the multi-layer system and reduces the adhesive strength between the Si-carrier substrate and the multi-layer system. The adhesive strength is reduced in particular by more than 50%, preferably more than 75%, still more preferably more than 90%.

### Substrates and Carrier Substrate

The substrates and carrier substrates can have any shape, but are preferably circular. The diameter of the substrates is in particular industrially standardised. The industrially standardised diameters for wafers are 1 inch, 2 inches, 3 inches, 4 inches, 5 inches, 6 inches, 8 inches, 12 inches and 18 inches. The carrier substrates are adapted in size and shape to the size and shape of the product substrates, in order that the handling technology used is as simple as possible. It is also conceivable to fix non-circular substrates such as for example panels, to process and release the latter from the carrier substrate.

The carrier substrate includes predominantly, preferably completely, of one or more of the undermentioned materials: glass, mineral (in particular Sapphire), semiconductor material (in particular silicon), polymer, composite material (SiC). Carrier substrates made of glass are often preferred in laser debonding, since electromagnetic beams in the UV-VIS wavelength range in combination with a UV-VIS-transparent bonding adhesive can preferably be used here in order to prevent heating as far as possible.

If carrier substrates of silicon are preferred, electromagnetic beams in the infrared (IR) wavelength region, in particular in the near and mid-IR, are required corresponding to the transparency of the Si carrier substrates.

In a further particularly preferred embodiment, the carrier substrate is produced from silicon. Si-carrier substrates are compatible with CMOS processes or front-end processes.

The transparency of the carrier substrate for the electromagnetic radiation is described by the degree of transmission, which gives the ratio of transmitted and irradiated radiation. The degree of transmission is however dependent on the thickness of the irradiated body and is therefore given related to a unit length of 1 cm.

Related to the selected thickness of 1 cm and to the respectively selected wavelength, the carrier substrate has a degree of transmission greater than 60%, preferably greater than 70%, still more preferably greater than 80%, most preferably greater than 90%, with utmost preference greater than 95%. The transparency is particularly preferably related to the wavelength of the debonding laser radiation.

The thermal conductivity of the carrier substrate preferably lies between 0.1 W/(m*K) and 5000 W/(m*K), more preferably between 0.5 W/(m*K) and 2500 W/(m*K), still more preferably between 1 W/(m*K) and 1000 W/(m*K).

The thickness of the carrier substrate can vary depending on the diameter and the requirements made on the structural stability.

### Laser Radiation

The laser radiation is selected in particular in such a way that the interface to be separated is achieved through the substrate and is absorbed intensely there by the multi-layer coating.

The laser energy is fed in the form of very short light pulses. In a preferred embodiment, it is ultrashort pulsed laser radiation.

According to a preferred embodiment, the separation results from a multi-photon excitation brought about by the laser radiation, in particular a femtosecond laser or a picosecond laser.

Laser radiation with picosecond (ps) pulses has been shown to be the optimum parameter combination for the processing by silicon in the case of thin metallic layers.

The separation of the multi-layer coating from the substrate takes place by carrier substrate-side irradiation with light, in particular laser radiation, which is absorbed intensely by the multi-layer coating at the interface or close to the interface between the materials to be separated.

The preferred silicon carrier substrate is opaque below a wavelength of 1.3 μm. Particularly preferred lasers and their wavelengths, which are suitable for the irradiation through the Si carrier substrates:
Nd:YAG (1.064 μm; 1.320 μm; 1.444 μm)
Ho:YLF (2.05 μm)
Ho:YAG (2.09 μm)
Cr:ZnSe, Cr:ZnS (MIR)

In a particularly preferred embodiment, a pulsed solid-state laser, preferably an Nd:YAG laser or an Ho:YAG laser is used. Pulsed solid-state lasers which operate in the infrared region above 1.3 μm are doped with ions of Er3+ (1.55 μm), Tm3+ (1.9 μm), Ho3+ (2.09 μm) or Cr3+ (2.4 μm).

Further preferred laser wavelengths with the application with Si carrier substrates are for example 1940 μm, 1960 μm or 2030 μm.

The power of the laser which provides the laser radiation, measured as light output, in particular radiation output, which can be continuously delivered to the substrate, amounts to 2 W.

The preferred wavelength range of the laser lies between >1100 nm and 10,000 nm, preferably between >1100 nm and 5000 nm, still more preferably between 1500 nm and 2500 nm.

Laser beams with at least two wavelengths can also be used. The layer thickness optimisation then takes place for both wavelengths for a multi-layer system.

The total energy of the laser radiation per substrate is set in particular between 1 mJ and 500 kJ, preferably between 100 mJ and 200 kJ, particularly preferably between 500 mJ and 100 kJ.

The laser beam can be operated in the continuous mode or preferably pulsed. The pulse frequency is set in particular between 0.1 Hz and 300 Mhz, preferably between 100 Hz and 500 kHz, particularly preferably between 1 kHz and 400 kHz, very particularly preferably between 1 kHz and 100 KHz.

The energy, which strikes the substrate stack per pulse of radiation, is in particular between 0.1 nJ and 1 J, preferably between 1 nJ and 900 μJ, particularly preferably between 1 nJ and 10 μJ.

A beam spot size lies in particular between 1 μm² and 10 mm², preferably between 5 μm² and 1 mm², particularly preferably between 400 μm² and 1502 μm² (measured at 1/e² of the beam intensity distribution of the laser spot on the substrate).

The spatial distance between the laser pulses at the substrate (pitch) lies in particular between 0.1 μm and 1000 μm, preferably between 1 μm and 500 μm, particularly preferably between 10 μm and 200 μm, most preferably between 20 and 100 μm.

The number of pulses per substrate stack, depending on the required total energy, amounts in particular to between 10 million pulses and 10 billion pulses, preferably between 10 million pulses and a billion pulses, particularly preferably between 20 million pulses and 100 million pulses.

The total energy of the laser radiation per substrate is in particular between 1 mJ and 500 kJ, preferably between 100 mJ and 200 kJ, particularly preferably between 500 mJ and 100 kJ.

The pulses have a length in the microsecond to the femtosecond region (μs-fs), preferably in the nanosecond to femtosecond region (ns-fs), in particular between 100 ns and 100 fs, preferably between 10 ps and 1 ps.

Very high power peaks can be reached with short pulses, without increasing the average laser power. Since the available pulse energy with shorter pulses is smaller by orders of magnitude with different pulse durations (in the region of J for high-power lasers compared to uJ for the “ultra-rapid” picosecond and femtosecond lasers), the total energy input into the material to be processed is reduced, which generally leads to a smaller heat-damaged zone on account of the shorter action time and the resultant reduced thermal diffusion.

By means of a high power density, it is possible to heat the material within the shortest possible time, in such a way that a removal or sublimation is thus achieved. The shorter action times thus lead to a smaller thermal energy input into the material lying beneath and thus to minimal damage of the area not processed.

With pulse durations below a few picoseconds, direct ablation by the laser radiation is assumed in the case of most materials, whereas in the case of longer pulse durations additional effects, which arise due to the interaction of the laser, laser-induced plasma and the material in different aggregate states, promote a thermally induced removal.

With high radiation intensities, plasma glow occurs in the case of the material ablation with laser radiation. After the occurrence of plasma glow, cumulative ionisation and thermal ionisation occurs to such an extent that material damages are no longer restricted to the laser focus. It is known from the prior art that the energy threshold for the formation of plasma glow markedly diminishes with diminishing pulse duration.

Overall, ultrashort pulses in the ps region are preferred, so that linear and non-linear absorption takes place at the multi-layer system. From a laser intensity of 1012 W/cm², the interaction between photons and atoms, apart from the one-photon absorption, also occurs due to the multiphoton absorption. Depending on the intensity magnitude, therefore, a linear or non-linear process can thus be the dominant part of the absorption. With intensities between 1012 to 1014 W/cm², which are reached with ultrashort pulses, multiphoton effects play a dominant role.

Pulses with high intensities and a pulse duration less than 100 ps can initiate plasma glow. Plasma glow advantageously leads to a markedly increased local absorption at the multi-layer system by the interaction of free electrons and ions with the residual electromagnetic field.

The pulse energy and/or the pulse duration and/or the length of a pulse train is preferably time-modulated by a control unit of a laser beam source generating the pulsed laser beam, wherein the modulation is preferably controlled via an external signal transmitter. The energy coupled by the laser beam into the process zone is preferably time-modulated by a modulation of the pulse duration of the laser pulses, wherein the pulse duration is preferably modulated between 0.1 ps and 20 ps.

Synonyms for the irradiation area are known to the person skilled in the art as spot size or beam spot, i.e. laser spot size.

The shape of the irradiation area is in particular circular, in other preferred embodiments elliptical or rectangular.

In laser debonding, laser light is coupled at the substrate side through a substrate that is as transparent as possible and absorbed in the adjacent release layer on the rear side. The laser light is preferably coupled by a largely transparent carrier substrate made of silicon. Si carrier substrates with the usual thicknesses between 725 and 775 μm are increasingly transparent for wavelengths from 1100 nm. Ultrashort pulses in the ps region are used, so that wavelengths greater than 1300 nm are preferred, wavelengths greater than 1900 nm are preferred still more, on account of the absorption by non-linear interactions of silicon in the range below 1300 nm. Shorter pulse durations require higher wavelengths for extensive transparency of the Si carrier substrates.

Optical and physical processes have a role to play in the interaction of the laser beam with the material. These are for example the numerical aperture (NA) of the lenses when focusing the laser beam in the material and the energy of the laser beam or the laser power density.

The following parameters lead to different interactions of ultrashort pulse lasers with material:
Pulse energy
Numerical aperture NA
Pulse duration
Pulse sequence frequency
Laser wavelength
Beam profile
Pulse form.

The following criteria are evaluated for a multi-layer system according to parameter settings:
ablation area per bombardment
debonding area or delamination area per bombardment
pulse energy for ablation threshold per bombardment
pulse energy for delamination threshold per bombardment

The following parameters of the multi-layer system can for example be determined:
thickness of the individual layers by means of simulation and in the test,
if necessary arrangement/sequence of the individual layers,
materials of the additional layer(s) if further layers are required.

The multi-layer systems are known to the person skilled in the art, as a result of which no material optimisation takes place. The materials of the multi-layer systems or coatings are known to the person skilled in the art, which are used in bonding and which are optimised in their layer thickness for interference for as high as possible absorption of the laser radiation. In many cases, it is not until the selection of the layer thicknesses that laser debonding is possible.

### Multi-Layer System and Multi-Layer Design Optimisation

The idea underlying the patent is to provide a multi-layer layer structure optimised via interference for bonding and laser debonding of substrates.

Many factors play a part in the absorption of radiation. The interaction is influenced both by the properties of the laser light and also those of the material. In the case of laser light, the most important are the wavelength, polarisation, angle of incidence and the spatial and temporal properties of the radiation, whereas in the case of the material the chemical composition and the microscopic or macroscopic properties primarily have an influence.

With different coatings, the effect of the scatter, reflection and absorption are used empirically in the prior art. An optimisation of the individual parameters is also common, but the adaptation of the layer thicknesses in order to increase the absorption in the optimum manner, thereby to minimise the losses due to reflection or transmission and to correlate the pulse duration with the layer thickness is hitherto unknown in the prior art. Factors such as for example laser wavelength, angle of incidence and material of the layers are kept constant.

The multi-layer design optimisation uses existing materials and coatings known to the expert in the area of the semiconductor industry, which in particular are optimised in their layer thickness, in such a way that maximum absorption is achieved via interference of the electromagnetic radiation on the multi-layer system.

The layer thicknesses lie in the sub-wavelength region, so that for an incident wave the multi-layer system has a different wave impedance from that of the individual used materials of the individual layers. The absorption of the multi-layer system is thus markedly improved.

If electromagnetic radiation can be absorbed in a material, the strength of the absorption is described by a material parameter, the degree of absorption, which as a rule is dependent on a plurality of parameters (temperature, wavelength etc.). The absorption or the degree of absorption is given between 0 and 1. A part of the radiation striking the surface of a body is usually reflected, a part is passed through the body and the remainder is absorbed. The absorbed energy increases the internal energy of the body. The degree of absorption (also absorption coefficient or spectral absorption coefficient SAK) indicates the fraction of the incident radiation that is absorbed. It can assume values between 0 and 1. The degree of absorption can depend on the irradiation direction and the frequency of the incident radiation.

If the absorption for different wavelengths and different layer thicknesses of a selected layer from a multi-layer system is represented in a graph, the representation of ranges of different absorption is possible. Generally, the absorption is primarily a lossy interaction of the electromagnetic field in material, which (usually) can be described by the electrical susceptibility and therefore by the complex-valued refractive index n+ik. Even non-linearities, which precisely play a part in the case of short pulses, e.g. when the response to an increase of the electric field increases proportional to the higher power, can be thus represented. In addition, simulations are used to show that, by changing the thin layer thicknesses in the nm region, an increase in the absorption of the entire multi-layer system can be achieved, through the emergence of multiple interferences of the interfaces between the individual layers of the multi-layer system.

The laser wavelength is preferably constant and two parameters, in particular layer thicknesses d1 and d2 of two layers from the multi-layer system, are varied at the same time and the absorption is calculated. By the optimisation of the layer thicknesses in the multi-layer system, a higher degree of absorption and a reduction of losses due to scatter or reflection and thus a greater laser debonding efficiency can be achieved. Scatter and diffraction effects can also be used in order to change the propagation direction of the light and thus to increase the interaction duration. Scatter and diffraction effects can also be used in order to protect the next layer lying beneath or product substrate lying beneath.

Optimisation of the layer thicknesses for each individual layer L1 to Ln of a multi-layer system comprising layers L1 to Ln, preferably L1 to L3, is carried out, wherein the absorption of the entire multi-layer system is determined numerically and also measured experimentally. The individual influences of the layers are investigated and optimised with regard to efficiency and stability of the effect.

The separation of the multi-layer system from the substrate takes place by substrate-side irradiation with light, in particular laser radiation, which is intensely absorbed by the multi-layer coating at the interface or close to the interface between the materials to be separated. The exemplary following effects at the adjacent layers are used: constructive interferences, scatter, diffraction and phase shifts.

The layers of the multi-layer system can be applied by means of chemical or physical vapour deposition, sputtering, vapour deposition, epitaxy and/or by means of spin-coating, as well as combinations thereof or other suitable techniques.

Due to the increased, optimised local absorption of the coating, an anti-reflection coating, antireflective layer, or AR is advantageously not necessary to markedly reduce the Fresnel reflection.

An additional bonding layer, in particular a bonding adhesive, is advantageously also not necessary, since the multi-layer system, which contains an in particular metallic or metal-containing photothermal multi-layer conversion layer, is at the same time also a bonding layer. An additional sacrificial layer is also not required.

The absorbed energy induces a decomposition of the multi-layer coating, wherein a separation of the interface between the substrate and the coating takes place. Decomposition mechanisms can for example be sublimation or chemical reactions. The decomposition can be initiated both thermally and photochemically. The separation is in particular assisted if gaseous products arise during the decomposition.

The at least one layer of the multi-layer system preferably includes the following compounds or elements, individually or in combination:
Metals, for example Ti, Au, Ag, Cu, Fe, Ni, Al, Cr, Pt, Sn
alloys,
semiconductors (e.g. Ge)
compounds, especially nitride compounds, in particular TiN, TaN, AlN, GaN, InN, SiN, Si3N4
compounds, in particular of oxide compounds, in particular SiO2, TiO2
compounds, in particular dielectrics
ceramic material, in particular silicon carbide (SiC) and aluminium oxide (Al2O3)
high-absorbing non-metals, in particular polymers with nanoparticles (polymers with Al- or C-particles)

The individual layers of the multi-layer system can include a material or a material combination from one of the main groups 3 (boron group), 4 (carbon group) and 5 (nitrogen group) of the periodic system of elements.

In a less preferred embodiment, the material is not applied over the whole area, but for individual layers of the multi-layer system as 2D-structures, for example graphene, or 3D-structures.

The multi-layer system is applied as a layer sequence of different compounds or elements on the product substrate and/or on the carrier substrate. Any number n of coatings can be constituted as a multi-layer system (L1 to Ln). Preferably, up to three layers are used in the multi-layer system (L1 to L3).

In a further embodiment, at least one compound or one element is applied in a number of times alternatingly.

The individual layers can serve for example as selective absorber layers or as phase shifters. Examples of absorbers are metals such as aluminium (Al) or gold (Au). Silicon dioxide (SiO2) can for example be used as an auxiliary layer and/or as a phase shifter, in order to position the field maximum of the wavelength inside the selective absorber. The layer thicknesses lie in the lower nm region. Thicker (metal) coatings can serve as mirrors if required.

Preferably, the further layers such as a sacrificial layer and/or an antireflection layer and/or a relaxation layer and/or a bonding adhesive are not required and are dispensed with.

The individual layers of the multi-layer coating have thicknesses between 1 nm and 10 μm, preferably between 1 nm and 1 μm, still more preferably between 5 nm and 500 nm. Due to the very thin layer sequence, a high interaction with the electromagnetic radiation is possible. This high interaction with very thin layers is used for simplified laser debonding. The layer thicknesses (nm-region) are reduced due to the optimisation of the individual layer thicknesses of a multi-layer system, as a result of which less material advantageously has to be applied.

Metals are strong absorbers and can hold back the laser radiation already from a layer thickness of <100 nm. In contrast, organic absorbers usually require a layer thickness of >3 μm in order to absorb 67% of the incident light.

The thickness of the multi-layer system preferably lies between 1 nm and 10 μm, still more preferably between 5 nm and 1 μm, most preferably between 10 nm and 1 μm.

Laser debonding optimisation process for a substrate stack with a multi-layer system and a silicon carrier substrate

An optimisation process for the separation by debonding or delamination along the interface by means of laser irradiation comprises for example the following steps:
Laser selection. Silicon as the carrier substrate is predominantly transparent at a wavelength λ>1300 nm or at λ>1900 nm, so that lasers in the near infrared (NIR) and mid-infrared (MIR) are selected, which exhibit a low linear and non-linear absorption in the Si carrier substrate;
existing materials of a multi-layer bonding layer are used between an Si carrier substrate and a product substrate; the multi-layer system enables an optimisation guided via interferences of the absorption required for laser debonding. The individual layers of the multi-layer system can serve, for example, depending on layer thickness, as selective absorber layers or as phase shifters or as mirrors and thus maximise overall the absorption at the multi-layer system. Examples of absorbers are metals such as aluminium (Al) or gold (Au). Silicon dioxide (SiO2) and aluminium nitride (AlN) can for example be used as phase shifter layers, in order to position the field maximum of the wavelength within the selective absorber. The layer thicknesses lie in the lower nm-region. Thicker coatings can serve as mirrors if need be. Depending on the layer thickness, a metal layer can be used for example as a mirror-layer (layer thickness >100 nm) or as a selective absorber layer (layer thickness <10 μm).
Laser efficiency and laser quality optimisation. In a preferred embodiment, it concerns ultrashort pulsed laser radiation. Laser source and laser wavelength are fixed parameters. The following laser parameters are for example optimised: pulse duration, pulse sequence frequency, energy, shape of irradiation area per pulse, multi-spot lasers.
Optimisation of the material thicknesses. The material layers are optimised in their layer thickness in such a way that maximum light absorption is achieved and reflection losses are minimised via interference. The increase in absorption due to the optimisation of the layer thicknesses is spatially localised and intensified inside the multi-layer system. Exceeding or falling below the optimum layer thicknesses of the individual layers of the multi-layer system would lead to a marked reduction in the absorption.

The optimisation of the layer thicknesses takes place in particular by simulation and/or laser debonding tests on the substrate stack with the layer thicknesses selected from the simulation. The residual bonding strength in the laser debonding, the form of ablation and homogeneity are investigated in the test. The produced system is also examined with regard to stability of the production and processing parameters.

### BRIEF DESCRIPTION OF THE DRAWINGS

Further advantages, features and details of the invention emerge from the following description of preferred examples of embodiment and with the aid of the drawings. The latter show diagrammatically:

FIG. 1a is a cross-sectional view of a substrate stack consisting of a carrier substrate, a multi-layer system with three layers and a product substrate with functional units.

FIG. 1b is a cross-sectional view of a substrate stack consisting of a carrier substrate, a multi-layer system with three layers and a product substrate with structuring.

FIG. 1c is a cross-sectional view of a substrate stack including a carrier substrate, a multi-layer system with two layers and a product substrate.

FIG. 2 is a cross-sectional view of a product substrate-carrier substrate stack with a diagrammatic representation of optical components for the irradiation of the multi-layer system with laser radiation.

FIG. 3a is a diagrammatic representation of the absorption spectrum A of a multi-layer system, which shows the absorption of a multi-layer system including three layers L1, L2 and L3, where thickness d1 of layer L1 and the wavelength are changed, whereas the thickness of layers L2 and L3 remain unchanged.

FIG. 3b is a diagrammatic representation of absorption spectrum A of a multi-layer system, which shows the absorption of a multi-layer system including two layers L1 and L2, where thickness d1 of layer L1 and thickness d2 of layer L2 are changed, whereas the laser wavelength remains unchanged.

Identical components or components with the same function have been denoted by the same reference numbers in the figures.

### DETAILED DESCRIPTION OF THE INVENTION

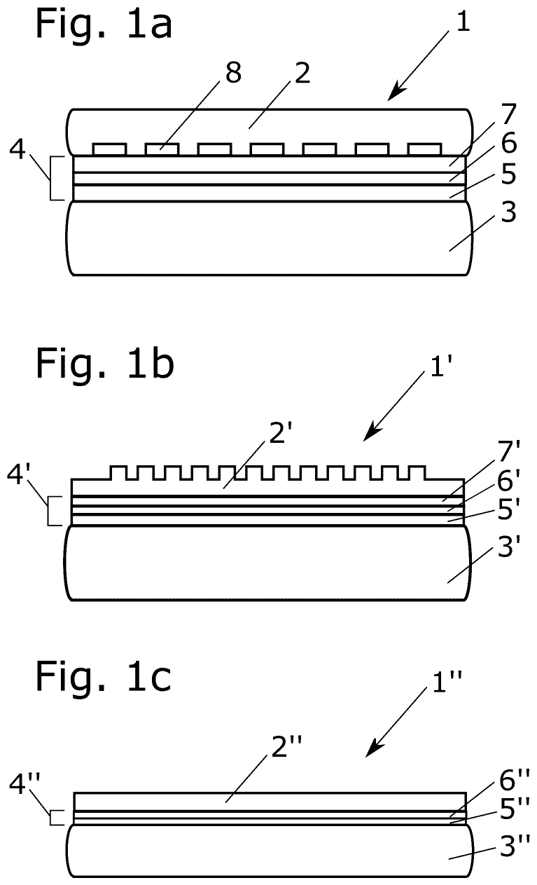

According to FIG. 1a, three layers L1 (5), L2 (6) and L3 (7) are applied for example over the whole area on product substrate 2 and/or carrier substrate 3. Structures 8 are located in and/or on product substrate 2. Layer thicknesses d1, d2 and d3 of the respective layers L1 (5), L2 (6) and L3 (7) are optimised. Multi-layer system 4 thus includes a plurality of layers 5, 6, 7, which are selected in such a way that multi-layer system 4 leads to a maximum absorption of the laser radiation in a laser debonding process. Layer structure 4 optimised via interference enables improved and simpler laser debonding, wherein no additional layers are required for the protection of the substrates or for the bonding of the substrates such as for example an antireflection coating and/or a relaxation layer and/or a bonding adhesive.

Individual layers 5, 6, 7 of multi-layer system 4 have thicknesses between 1 nm and 1 μm, preferably between 1 nm and 500 nm, still more preferably between 1 nm and 250 nm. Due to the very thin layer sequence, a high interaction with the electromagnetic wave of the laser irradiation is possible.

The thickness of multi-layer system 4 preferably lies between 1 nm and 10 μm, still more preferably between 5 nm and 2 μm, most preferably between 10 nm and 1 μm, with utmost preference between 10 nm and 500 nm.

After the coating of multi-layer system 4 on product substrate 2 and/or carrier substrate 3, product substrate 2 is bonded to the carrier substrate 3 in a (temporary) bonding process by alignment, contacting and bonding according to FIG. 1a. The (temporary) bonding technologies are known to the expert in the field.

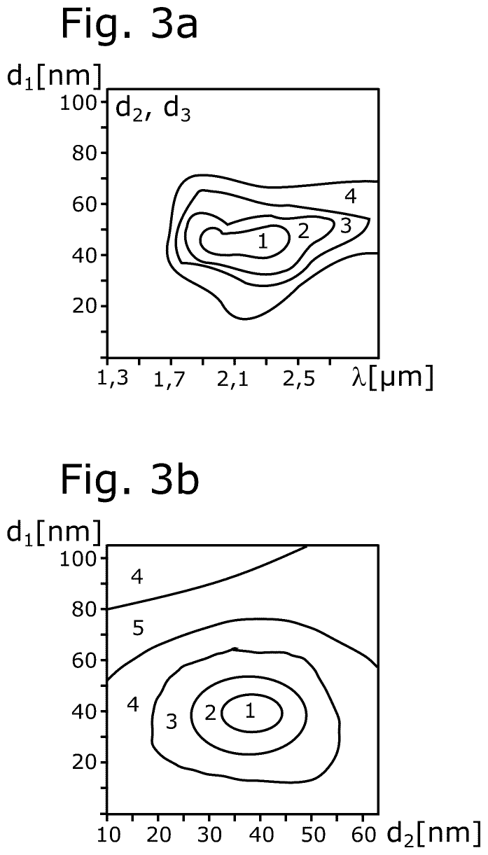

FIGS. 1a and 1b represent three coatings L1 to L3 (5, 5′, 6, 6′, 7, 7′), but any other number n of coatings can also be constituted. FIG. 1c shows for example an embodiment of the multi-layer system with two coatings 5″, 6″. An optimisation of the layer thicknesses is carried out for each individual layer L1 to Ln of a multi-layer system including layers L1 to Ln, wherein the absorption of the entire multi-layer system is measured. For example, two layer thicknesses d1 and d2 are first varied simultaneously in a simulation with constant wavelength and the resultant absorption determined according to FIG. 3b. Layer thicknesses d1max and d2max of coating 5″, 6″, which lead to a maximum, efficient and stable absorption, are selected. Further variable laser parameters are in particular optimised by analysis in the laser debonding of the substrate stack in the test.

FIG. 1b shows a further embodiment of a substrate stack 1′ including carrier substrate 3′, multi-layer system 4′ with three layers L1 to L3 (5′, 6′, 7′) and a product substrate 2′ with structuring.

FIG. 1c shows another embodiment of a substrate stack 1″ including carrier substrate 3″, multi-layer system 4″ with two layers L1 (5″) and L2 (6″) and the product substrate 2″.

In the following section, a plurality of non-limiting examples of multi-layer systems (for example layers L1-L2-L3 or L1-L2) are given on the basis of the multi-layer systems from FIGS. 1a to 1c. Multi-layer systems, which are known to the person skilled in the art and which are used in the semiconductor industry, in particular also for CMOS-compatible or front-end-compatible processes consist for example of:
SiO2-metal-SiO2 (L1-L2-L3),
SiO2-metal 1 (L1-L2),
Metal 1 (layer thickness d1)-oxide or nitride compound (for example SiO2)-Metal 1 (layer thickness d2) (L1-L2-L3),
SiO2-nitride compound-SiO2 (L1-L2-L3),
Nitride compound-SiO2 (L1-L2),
Oxide or nitride compound (for example SiO2)-metal 1-metal 2 (L1-L2-L3),
Metal 1-metal 2-metal 3 (L1-L2-L3),
Metal 1-metal 2 (L1-L2),
Metal 1-metal 2-metal 1 (L1-L2-L3).

In particular, the following multi-layer systems are given for laser debonding, which are applied on a 300 mm silicon carrier substrate (with a thickness of 775 μm with surfaces polished on both sides):

| | Layer L1 with 40 to 50 nm | Layer L2 with 250 nm |
|---|---|---|
| | layer thickness | layer thickness |
| System 1 | Ti | TEOS (CMP) |
| System 2 | Al | TEOS (CMP) |
| System 3 | AlN | TEOS (CMP) |
| System 4 | TaN | TEOS (CMP) |
| System 5 | Ge | TEOS (CMP) |
| System 6 | TiN | TEOS (CMP) |

The TEOS layer is a layer of amorphous silicon dioxide (SiO2) and is preferably fine polished by chemo-mechanical polishing (CMP).

The 300 mm silicon carrier substrate also has a thickness of 725 μm in an alternative embodiment.

The bonded product substrate (also of silicon) follows after layer L2. During debonding, the laser first penetrates the 775 μm silicon carrier layer, then layers L1 and L2.

The laser wavelength is determined by the selection of the carrier substrate and is not changed. The laser angle of incidence also remains constant.

Further specific examples of layer systems:
SiN—SiO2 (L1-L2)
TEOS (50-250 nm)-TiN (20-100 nm)-TEOS (50-400 nm) (L1-L2-L3)
TiN (50 nm)-TEOS (400 nm) (L1-L2)
SiO2 (thermally, 50-100 nm)-TiN (50 nm)-TEOS (400 nm) (L1-L2-L3)

The at least one layer of the multi-layer system preferably includes the following compounds or elements, individually or in combination:
Metals, for example Ti, Au, Ag, Cu, Fe, Ni, Al, Cr, Pt, Sn
alloys,
semiconductors (e.g. Ge)
compounds, especially nitride compounds, in particular TiN, TaN, AlN, GaN, InN, SiN, Si3N4
compounds, in particular of oxide compounds, in particular SiO2, TiO2
ceramic material, in particular silicon carbide (SiC) and aluminium oxide (Al2O3)
high-absorbing non-metals, in particular polymers with nanoparticles (polymers with Al- or C-particles)

The individual layers of the multi-layer system can for example serve, depending on the layer thickness and material, as selective absorber layers, auxiliary layers and/or phase shifter layers or as mirror layers and thus overall maximise the absorption of the multi-layer system. A metal layer, for example, depending on the layer thickness, can be used as a mirror layer (layer thickness >100 nm) or as a selective absorber layer (layer thickness <10 μm). Silicon dioxide (SiO2) and aluminium nitride (AlN) can for example be used as phase shifter layers.

The absorptive layer is usually the middle layer in the case of three layers. In the case of two layers, the absorptive layer is usually the first layer. The absorptive layer absorbs the energy of the laser radiation.

In an example, the absorptive layer includes SiN and the auxiliary layer of SiO2. As a result of the interaction of the SiN and SiO2 layers, NOx gases arise which lead to layer splitting and thus debonding.

In a preferred embodiment, the layer thickness of the absorptive layer amounts to between 10 nm and 200 nm and the thickness of the auxiliary layer(s) to between 1 and 1000 nm.

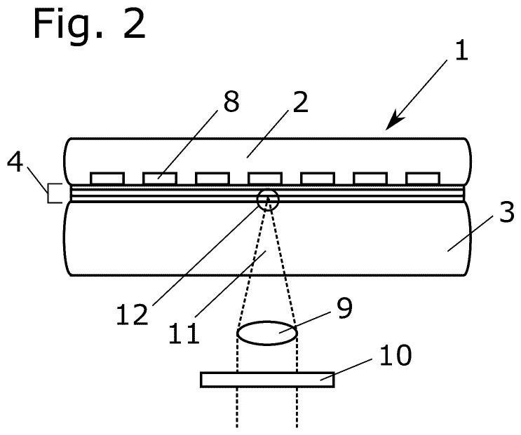

FIG. 2 shows a cross-sectional view of a product substrate-carrier substrate stack 1 during laser debonding by irradiation of multi-layer system 4 with laser radiation 11. A suitable light source is for example a light source which emits ultrashort light pulses with a duration of 10 ps to 50 ps and a repetition frequency of 1000 Hz.

Ultrashort pulsed laser beam 11 is focused on a lens 9 in process zone 12. A relative movement between substrate stack 1 and laser beam 11 takes place with substrate stack positioning and/or beam positioning (not represented). Further optical elements comprise for example beam-shaping elements, scanners, modulators etc. and are known to the person skilled in the art.

The relevant wavelength range for Si as a carrier substrate lies between 1940 to 2140 nm, because Si exhibits a very marked non-linearity and the non-linear absorption/diffraction reaches up to over 1700 nm, which leads to autofocusing. An important factor here is also the energy and power density required for the ablation.

The wavelengths and the laser selection are often different with other carrier materials (for example Sapphire).

FIG. 3a describes a process sequence for the optimisation of an exemplary multi-layer system 4 includes three layers L1, L2 and L3 (5, 6, 7) according to FIG. 1a, which is intended to be used for the temporary bonding and laser debonding of product substrate 2 and carrier substrate 3. It is conceivable that product substrate 2, 2′, 2″ has no topography, either because no structures 8 are present or because structures 8 have been directly produced in product substrate 2, 2′, 2″. Alternatively, the structures can for example be chips or structured coatings and form a topography.

According to FIG. 3a, thickness d1 of first layer L1 varies between 0 and 100 nm, in order to determine the maximum absorption of the multi-layer system with different wavelengths. Area 1 in FIG. 3a shows the maximum absorption. Areas in FIG. 3a with an increasing number show a diminishing absorption of the multi-layer system. Thickness d2 and d3 of the other two layers L2 and L3 are kept constant. The individual thicknesses of the layers influence the interference pattern and thus the absorption of the multi-layer system. By determining the optimum layer thicknesses d1, d2 and d3, the maximum absorption of the multi-layer system is determined for improved and simplified laser debonding. Representations according to FIG. 3a are represented with simulations and determined with the measurement series. The optimisation or changing of materials of the individual layers is dispensed with and simplified laser debonding is achieved through maximum absorption with existing layer systems by optimisation of the layer thicknesses. The absorption can be increased from <10% to >90%.

The absorptivity is calculated primarily with known solution algorithms by means of linear evaluation by Fresnel equations of multi-layer systems, based on layer thicknesses and (linear, but complex-valued) refractive indices. Moreover, the non-linear properties can be used in more complex simulations, which also take account of the field strength distributions.

In an alternative embodiment to FIG. 3a, the absorption can be represented in dependence on two layer thicknesses d1 and d2 according to FIG. 3b, for example for a system including two layers L1 and L2 with a selected laser wavelength. If the layers, the substrate and the carrier substrate from a given substrate stack are known, layer thickness d of the individual layers of the multi-layer system is easiest to control and to change. Layer thickness d of the individual layers of the multi-layer system is thus primarily optimised. The laser wavelength and the laser angle (angle of incidence) remain in particular unchanged. If a multi-layer system includes two layers, both layer thicknesses d1 and d2 can be simultaneously varied according to FIG. 3b. The selected parameters, in particular for example two layer thicknesses d1 and d2, are varied and the degree of absorption in the debonding structure is calculated. The degree of absorption in the debonding structure must be as high as possible. Up to a maximum of three layers are preferably used in order to maximise the absorption. Analogous to FIG. 3a, area 1 in FIG. 3b shows the maximum absorption. Areas with an increasing number show a diminishing absorption of the multi-layer system. Area 1 with high absorption in the represented graphic must be large enough in order not to be too sensitive to changes.

### LIST OF REFERENCE NUMBERS

1, 1′, 1″ substrate stack
2, 2′, 2″ product substrate
3, 3′, 3″ carrier substrate
4, 4′, 4″ multi-layer system
5, 5′, 5″ layer L1
6, 6′, 6″ layer L2
7, 7′ layer L3
8 structure
9 lens
10 optical element
11 laser beam
12 process zone

1. A method for providing a multi-layer system including at least two layers for temporarily bonding substrates to form a substrate stack, the method comprising the following steps:
i) providing a multi-layer system,
ii) determining a degree of absorption of the provided multi-layer system for laser radiation of a specific wavelength,
iii) varying at least one parameter of the provided multi-layer system,
iv) determining the degree of absorption of the provided multi-layer system for the laser radiation of the specific wavelength with the at least one parameter being varied according to step iii), and
v) repeating steps i) to iv) until the degree of absorption that is greatest is determined,
wherein, in each case, in step i), the multi-layer system with the greatest degree of absorption is provided.

2. The method according to claim 1, wherein the at least one parameter of the multi-layer system is a layer thickness of a layer of the multi-layer system.

3. The method according to claim 2, wherein the at least one parameter of the multi-layer system is a layer thickness of a further layer of the multi-layer system.

4. The method according to claim 1, wherein the wavelength in the determination in step ii) and iv) lies between 1100 nm and 10,000 nm.

5. A substrate stack, comprising:
the multi-layer system provided according to the method of claim 1,
wherein the at least two layers are made of different materials.

6. The substrate stack according to claim 5, wherein the multi-layer system has a total thickness between 1 nm and 10 μm.

7. The substrate stack according to claim 5, wherein each of the at least two layers has a layer thickness between 1 nm and 1 μm.

8. The substrate stack according to claim 5, wherein one of the at least two layers has a layer thickness between 25 nm and 75 nm.

9. The substrate stack according to claim 5, wherein at least one of the at least two layers includes titanium (Ti), aluminium (Al), aluminium nitride (AlN), tantalum nitride (TaN), germanium (Ge), tin titanium nitride (TiN) or copper (Cu).

10. The substrate stack according to claim 5, wherein at least one of the at least two layers includes amorphous silicon dioxide.

11. The substrate claim 5, further comprising:
a carrier substrate, and
a product substrate,
wherein the carrier substrate is bonded with the product substrate by the multi-layer system.

12. The substrate stack according to claim 5, wherein the multi-layer system does not comprise any polymer-based bonding adhesive.

13. The substrate stack according to claim 5, wherein the multi-layer system does not comprise an antireflection layer.

14. A method for bonding substrates to form a substrate stack according to claim 5, compising the following steps:
1) providing a carrier substrate, and
2) bonding a product substrate to the carrier substrate.

15. A method for debonding a substrate stack, comprising the following steps:
a) provision the substrate stack according to claim 5,
b) irradiating the multi-layer system through at least one substrate of the substrate stack with laser radiation of a specific wavelength, and
c) separating the substrate stack in a region of the multi-layer system.
